(19) United States
(12) Patent Application Publication
(10) Pub. No.: US 2025/0379168 A1
(43) Pub. Date: Dec. 11, 2025

(54) Semiconductor Packages and Methods of Forming Same

(71) Applicant: Taiwan Semiconductor Manufacturing Co., Ltd., Hsinchu (TW)

(72) Inventors: Chien-Yuan Huang, Hsinchu (TW); Li Wang, Hsinchu (TW); Shih-Chang Ku, Taipei City (TW)

(21) Appl. No.: 18/737,238

(22) Filed: Jun. 7, 2024

(51) Int. Cl. H01L 23/00; H01L 25/065

(52) U.S. Cl. CPC H01L 24/06; H01L 24/05; H01L 24/08; H01L 24/80; H01L 25/0657; H01L 2224/05546; H01L 2224/05555; H01L 2224/06051; H01L 2224/06519; H01L 2224/08145; H01L 2224/80895; H01L 2224/80896

(57) ABSTRACT

In an embodiment, a method includes forming a device layer along a substrate; forming a first interconnect structure over the device layer; forming a metal pad over the first interconnect structure; forming first bonding pads over and electrically connected to the first interconnect structure; and forming a second bonding pad over and electrically isolated from the first interconnect structure, in a plan view the first bonding pads comprising four corners of a frame around a portion of the second bonding pad.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a trend for smaller and more creative packaging techniques of semiconductor dies has emerged. An example of such packaging systems is Package-on-Package (POP) technology. In a POP device, a top semiconductor package or component is stacked on top of a bottom semiconductor package or component to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 2C illustrate cross-sectional views of intermediate steps during a process for forming an integrated circuit die, in accordance with some embodiments.

FIG. 3 illustrates a cross-sectional view of intermediate steps during a process for forming a semiconductor package, in accordance with some embodiments.

FIGS. 4A through 4C illustrate cross-sectional views of intermediate steps during a process for forming an integrated circuit die, in accordance with some embodiments.

FIG. 5 illustrates a cross-sectional view of intermediate steps during a process for forming a semiconductor package, in accordance with some embodiments.

FIGS. 6A through 6F illustrate cross-sectional views of intermediate steps during a process for forming an integrated circuit die, in accordance with some embodiments.

FIGS. 7 through 10 illustrate cross-sectional views of intermediate steps during a process for forming a semiconductor package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a semiconductor package may be formed by bonding a first integrated circuit die to a second integrated circuit die. The integrated circuit dies may be formed with bonding structures that include bonding pads embedded in a dielectric bonding layer. In accordance with various embodiments, the bonding pads of the integrated circuit dies may include electrical pads to transmit electrical signals and thermal pads to dissipate heat. As discussed in greater detail below, the thermal pads may be fabricated with high design flexibility, such that the thermal pads may include a variety of shapes, depths, and locations to achieve thermal dissipation benefits. The bonding structures may be bonded to one another in a face-to-face attachment of the integrated circuit dies. As a result, the integrated circuit dies and the semiconductor packages may be manufactured at greater yields, with improved performances, and higher reliability.

Various embodiments are described below in a particular context. Specifically, a chip on wafer (CoW) type system on an integrated chip (SoIC) package is described. However, various embodiments may also be applied to other types of semiconductor packaging technologies, such as, integrated fan-out (InFO) packages, or the like. Embodiments are discussed below wherein a first integrated circuit die (e.g., in the form of a singulated die) is attached to a second integrated circuit die (e.g., in the form of a wafer). It should be appreciated that the first integrated circuit die may remain in wafer form, while the second integrated circuit die is in singulated die form. In addition, the first and second integrated circuit dies may be attached to one another while both are in wafer forms or both in singulated die forms.

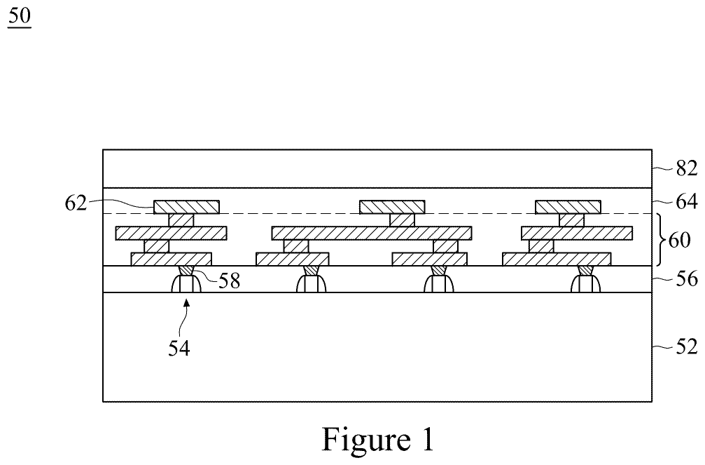

FIGS. 1 through 10 illustrate intermediate steps in the formation of integrated circuit dies 50 and bonding integrated circuit dies 50A/50B to one another, wherein either or both of the integrated circuit dies is formed with a bonding structure 80 that includes electrical pads 84E (e.g., electrical bonding pads) and one or more thermal pads 84T (e.g., thermal bonding pads). As discussed below, the thermal pad 84T may be in the form of a conductive frame (e.g., a continuous or a discontinuous conductive frame) or one or more other discrete conductive elements.

FIG. 1 describes intermediate steps in the formation of an integrated circuit die 50, which includes forming an integrated circuit (e.g., devices 54 and an interconnect structure 60) over a substrate 52 and forming a bonding structure 80 over the integrated circuit. One or more integrated circuit dies 50 may be further processed and packaged together into a semiconductor package 150. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

The integrated circuit die 50 may be formed at wafer level, which includes different device regions that are singulated in subsequent steps to form a plurality of integrated circuit dies (not separately illustrated). The integrated circuit die 50 may be processed according to applicable manufacturing processes to form integrated circuits. For example, the integrated circuit die 50 includes a semiconductor substrate 52, such as silicon, doped or undoped, or an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The semiconductor substrate 52 has an active surface (e.g., the surface facing upwards in FIG. 1), sometimes called a front side, and an inactive surface (e.g., the surface facing downwards in FIG. 1), sometimes called a back side.

Devices (represented by transistors) 54 may be formed in a device layer at the front surface of the semiconductor substrate 52. The devices 54 may be active devices (e.g., transistors, diodes, etc.), capacitors, resistors, etc. An inter-layer dielectric (ILD) 56 is over the front surface of the semiconductor substrate 52. The ILD 56 surrounds and may cover the devices 54. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 extend through the ILD 56 to electrically and physically couple the devices 54. For example, when the devices 54 are transistors, the conductive plugs 58 may couple the gates and/or source/drain regions of the transistors. The conductive plugs 58 may be formed of tungsten, cobalt, nickel, copper, silver, gold, aluminum, the like, or combinations thereof. An interconnect structure 60 is over the ILD 56 and conductive plugs 58. The interconnect structure 60 interconnects the devices 54 to form an integrated circuit. The interconnect structure 60 may be formed by, for example, metallization patterns in dielectric layers on the ILD 56. The metallization patterns include metal lines and vias formed in one or more low-k dielectric layers. The metallization patterns of the interconnect structure 60 are electrically coupled to the devices 54 by the conductive plugs 58.

The integrated circuit die 50 may further include pads 62 (e.g., metal pads), such as aluminum pads, to which external connections are made. The pads 62 are on the active side of the first integrated circuit die 50, such as in and/or on the interconnect structure 60. One or more passivation films 64 may be disposed over the pads 62.

In some embodiments, some of the pads 62 may be used as test pads before additional processing steps are performed. For example, the pads 62 may be probed as part of a wafer-acceptance-test, a circuit test, a Known Good Die (KGD) test, or the like. The probing may be performed to verify the functionality of the devices 54 (e.g., active or passive devices), other electrical components, or various electrical connections within the integrated circuit. For example, the probing may be performed by contacting a probe needle (not specifically illustrated) to the pads 62. The integrated circuit dies 50 within the wafer that pass the circuit probe testing will be deemed KGDs and may be utilized in further processing after a subsequent singulation process.

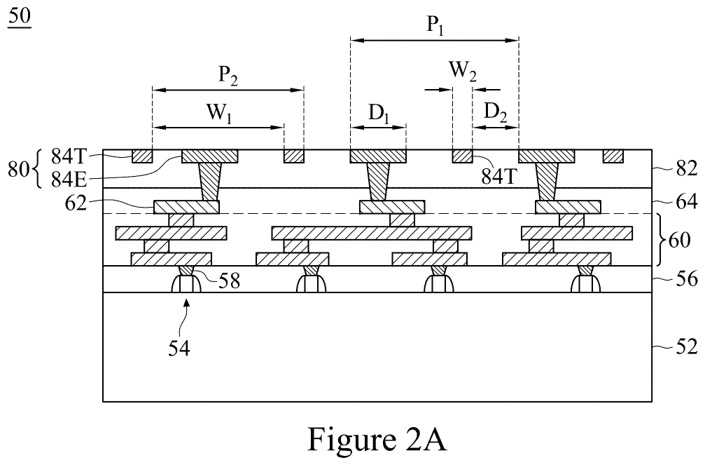

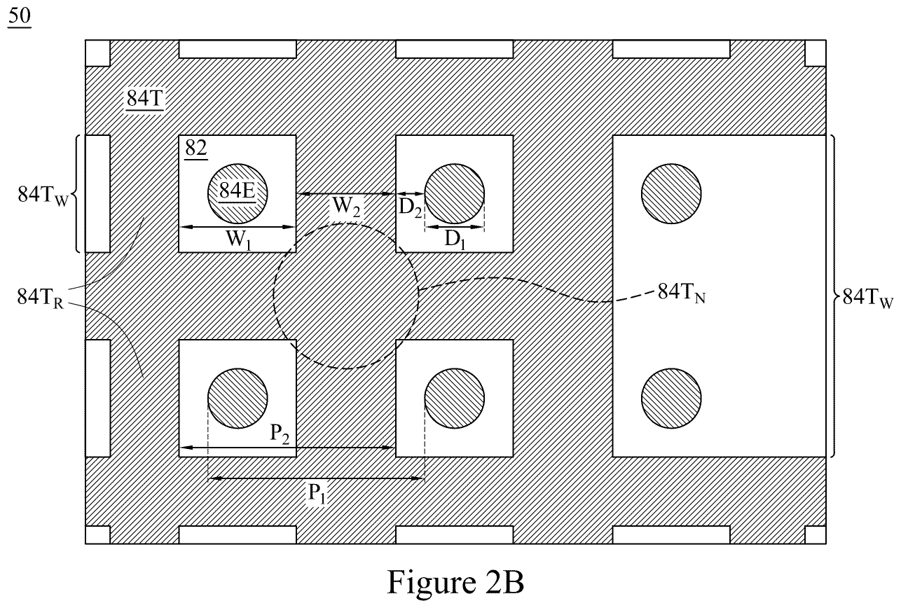

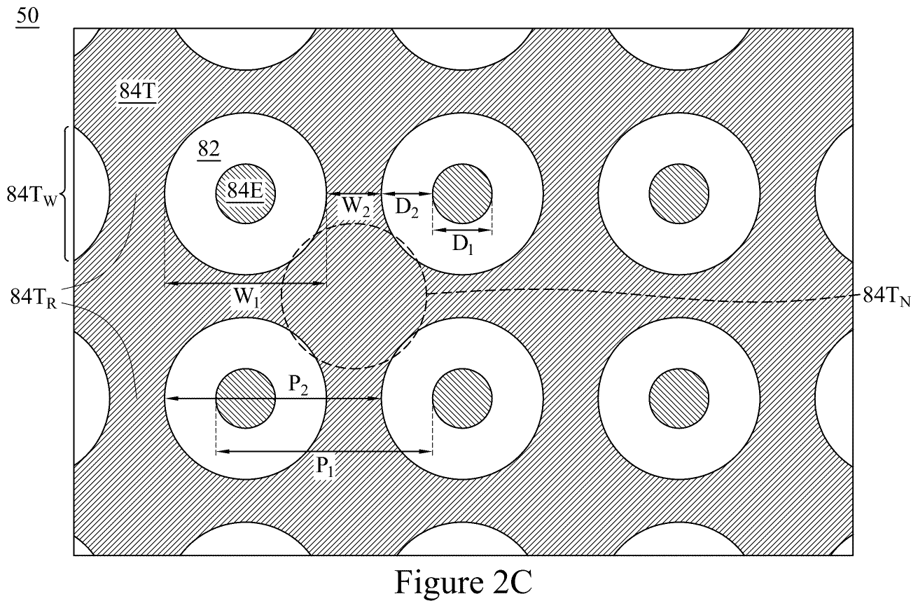

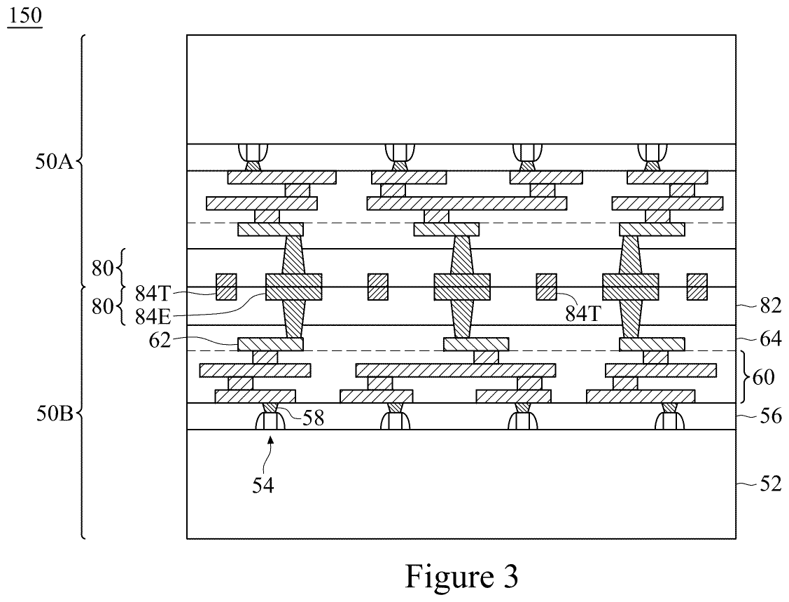

FIGS. 2A through 2C illustrate formation of a bonding structure 80 comprising, e.g., bonding pads 84 within a dielectric bonding layer 82. The bonding pads 84 include electrical pads 84E and one or more thermal pads 84T, wherein the electrical pads 84E will be used to transmit electrical signals of the integrated circuit die 50 and the thermal pad(s) 84T will be used to dissipate heat through and from the integrated circuit die 50. The bonding pads 84 will be used to attach the integrated circuit die 50 to another semiconductor component (see, e.g., FIG. 3). In particular, the electrical pads 84E may be bonded to bonding pads of another integrated circuit die 50, and the thermal pad(s) 84T may also contribute to attachment of the integrated circuit die 50 to the other integrated circuit die 50.

In accordance with some embodiments, the dielectric bonding layer 82 may be formed over the pads 62 and the interconnect structure 60. The dielectric bonding layer 82 may be any material suitable for achieving a dielectric-to-dielectric bond. In some embodiments, the dielectric bonding layer 82 may comprise silicon oxide, silicon nitride, silicon oxynitride, or the like, and the dielectric bonding layer 82 may be deposited using a suitable deposition process such as PVD, CVD, ALD, or the like. The electrical pads 84E may be formed using a dual damascene process or using one or more single damascene processes. The thermal pad(s) 84T may be formed in parallel (e.g., simultaneously) with the electrical pads 84E using a single damascene process.

The bonding pads 84 may then be formed in and through the dielectric bonding layer 82. The bonding pads 84 may be formed of a similar material (e.g., copper) and using similar processes as described above with respect to the interconnect structure 60. In some embodiments, openings are formed in the dielectric bonding layer 82. Some of those openings may have a total depth within the dielectric bonding layer 82, some of those openings may extend through the dielectric bonding layer and the passivation film 64 to expose underlying pads 62, and some of the openings may further extend past the pads 62 to expose other upper metallization layers of the interconnect structure 60.

The openings may be patterned into the dielectric bonding layer 82 and the passivation film 64 using photolithography or any suitable method (e.g., with multiple photo-masking steps and etching steps). Conductive material is then deposited in the various openings, and a removal process is performed to remove excess conductive material from an upper surface of the dielectric bonding layer 82. The removal process may include a planarization step may then be performed to substantially level surfaces of the bonding pads 84 and the dielectric bonding layer 82. For example, the removal process may include a chemical mechanical polish (CMP) process, a grinding process, the like, or combinations thereof.

The electrical pads 84E are the bonding pads 84 that extend to the pads 62 and/or the interconnect structure 60 for electrical connection. The electrical pads 84E are embedded in the dielectric bonding layer 82 and may extend partially through the passivation film 64. As illustrated, the electrical pads 84E have landing pad portions which are level with a major surface of the dielectric bonding layer 82. The electrical pads 84E also have via portions which extending through the dielectric bonding layer 82 (and the passivation film 64) to physically and electrically connect to the pads 62.

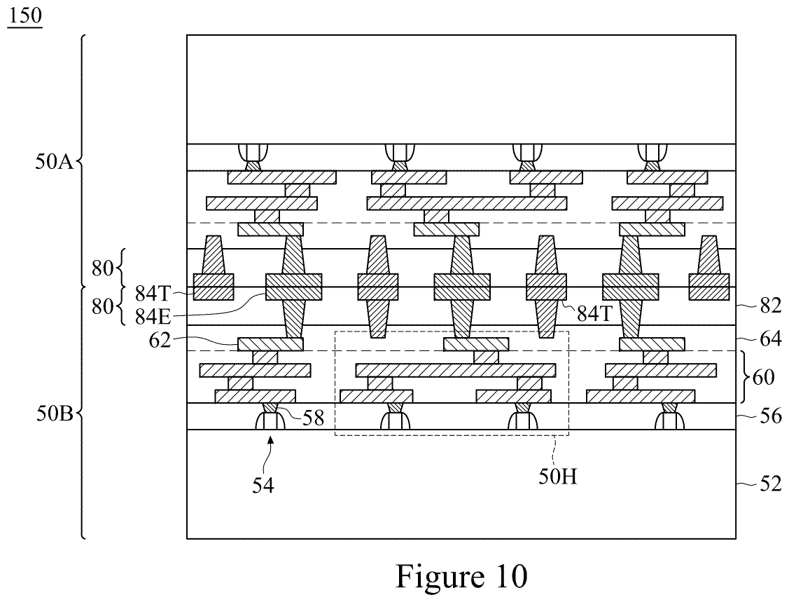

The thermal pads 84T are the bonding pads 84 which remain electrically isolated from the integrated circuit of the integrated circuit die 50 (e.g., the pads 62 and the interconnect structure 60). The thermal pads 84T are also embedded in the dielectric bonding layer 82. As illustrated, the thermal pads 84T may include landing pad portions without via portions. Note that other embodiments of the thermal pads 84T may include via portions (see FIG. 10).

As discussed above, in some embodiments, the electrical pads 84E are formed in a dual damascene process while the thermal pads 84T are formed in a single damascene process. The single damascene process for the thermal pads 84T may be performed in parallel (e.g., simultaneously) with the dual damascene process for the electrical pads 84E. For example, one of the etch steps to form openings for the electrical pads 84E may also form the openings for the thermal pads 84T, and the conductive material may be deposited and planarized for the electrical pads 84E and the thermal pads 84T simultaneously, similarly as described above. It should be appreciated that sub-processes for forming the electrical pads 84E and the thermal pads 84T may be performed in any suitable order (or in parallel).

FIGS. 2B and 2C illustrate plan views of the bonding structure 80 (e.g., the dielectric bonding layer 82, the electrical pads 84E, and the thermal pad 84T) of the integrated circuit die 50, in accordance with various embodiments. In the illustrated embodiments, the thermal pad 84T may be a conductive framework (e.g., a conductive frame, such as a continuous conductive frame) extending around and between the bonding pads 84. FIG. 2B illustrates the thermal pad 84T with rectangular (e.g., square) openings or windows 84T_{W} bounded by rails 84T_{R}, and FIG. 2C illustrates the thermal pad 84T with round (e.g., circular) openings or windows 84T_{W} bounded by rails 84T_{R}.

An upper surface of the bonding structure 80 has a metal density based on the proportion of the bonding pads 84 embedded in the dielectric bonding layer 82. For example, due to presence of the thermal pad 84T, the metal density may range from 50% to 80%, such as from 60% to 70%. In such embodiments, the electrical pads 84E may account for about 10% or less of the metal density and the thermal pad 84T accounts for a remainder of the metal density. For example, presence of the thermal pad 84T may increase the metal density by 6 to 7 times. As a result, thermal resistance of the integrated circuit die 50 may be reduced by up to 90% to 95%, thereby improving thermal dissipation benefits of the integrated circuit die 50. A metal density of greater than 50% (e.g., greater than 60%) ensures sufficient thermal dissipation benefits. In addition, a metal density of lesser than 80% (e.g., lesser than 70%) ensures that the upper surface of the bonding structure 80 includes a sufficient proportion of the dielectric bonding layer 82 for reliable bonding (see FIG. 3).

Referring to FIG. 2B, the conductive frame of the thermal pad 84T may comprise rectangular (e.g., square) windows 84T_{W} bounded by perpendicular rails 84T_{R}. As illustrated, the windows 84T_{W} contain the electrical pads 84E within rectangular frames. For example, in the illustrated embodiments, four rails 84T_{R} connect to form a frame having a window 84T_{W} which contains an electrical pad 84E. Optionally, some of the windows 84T_{W} may be large enough to contain two, four, or more of the electrical pads 84E (or none), such as the window 84T_{W} containing two of the electrical pads 84E as illustrated in the right-hand portion of FIG. 2B. The electrical pads 84E are spaced at a pitch P₁ which is between 2 times and 10 times a diameter D₁ (e.g., a critical dimension) of the electrical pads 84E. As such, the window 84T_{W} may have a width W₁ ranging from 2 times the diameter D₁ to 0.5 times the pitch P₁. In addition, the rails 84T_{R} may have a width W₂ ranging from substantially equal to the diameter D₁ to 0.8 times the pitch P₁.

As a result, the widths W₂ of the rails 84T_{R} are at least as large as the critical dimension (e.g., the diameter D₁) to avoid or reduce patterning challenges while also maintaining a sufficient distance D₂ from the electrical pads 84E to prevent parasitic effects. Moreover, the components of the thermal pad 84T (e.g., the rails 84T_{R} and the windows 84T_{W}) may have a pitch P₂ being substantially the same as the pitch P₁ (or multiples of the pitch PI for windows 84T_{W} which contain multiple electrical pads 84E). Forming the bonding structure 80 within these dimensions achieves the described thermal dissipation benefits while preventing parasitic effects between the electrical pads 84E and the thermal pad 84T.

As further illustrated, the electrical pads 84E may be viewed as framing at least a portion of the thermal pads 84T. For example, a portion of the thermal pad 84T where four rails 84T_{R} meet or intersect (e.g., a node 84T_{N}) is framed by at least four electrical pads 84E. In particular, four of these electrical pads 84E comprise four corners of a frame around the node 84T_{N} of the thermal pad 84T. In some embodiments, others of these electrical pads 84E may comprise portions of one or more sides of the frame. As illustrated, the node 84T_{N} may have a cross or rectangular (e.g., square) shape.

Referring to FIG. 2C, the conductive frame of the thermal pad 84T may comprise round (e.g., circular or oval) windows 84T_{W} bounded by convex rails 84T_{R}. As illustrated, the windows contain the electrical pads 84E within oval (e.g., round or circular) frames. For example, in the illustrated embodiments, four rails 84T_{R} connect to form a frame having a window 84T_{W} which contains an electrical pad 84E. In some embodiments (not specifically illustrated), some of the windows 84T_{W} may contain two, four, or more of the electrical pads 84E (or none). As noted above, the electrical pads 84E are spaced at the pitch PI which is between 2 times and 10 times the diameter D₁ (e.g., the critical dimension) of the electrical pads 84E. As such, the window 84T_{W} may have a width W, (e.g., a diameter) ranging from 2 times the diameter D₁ to 0.5 times the pitch P₁. In addition, the rails 84T_{R} may have a narrowest width W₂ ranging from substantially equal to the diameter D₁ to 0.8 times the pitch P₁.

As a result, the widths W₂ of the rails 84T_{R} are at least as large as the critical dimension (e.g., the diameter D₁) to avoid patterning challenges while also maintaining a sufficient distance D₂ from the electrical pads 84E to prevent parasitic effects. As illustrated, the distance D₂ may be substantially constant around perimeters of the electrical pads 84E. Moreover, the components of the thermal pad 84T (e.g., the rails 84T_{R} and the windows 84T_{W}) may have a pitch P₂ being substantially the same as the pitch P₁. Forming the bonding structure 80 within these dimensions achieves the described thermal dissipation benefits while preventing parasitic effects between the electrical pads 84E and the thermal pad 84T.

As further illustrated, the electrical pads 84E may be viewed as framing at least a portion of the thermal pads 84T. For example, a portion of the thermal pad 84T where four rails 84T_{R} meet or intersect (e.g., a node 84T_{N}) is framed by at least four electrical pads 84E. In particular, four of these electrical pads 84E comprise four corners of a frame around this portion of the thermal pad 84T. In some embodiments, others of these electrical pads 84E may comprise portions of one or more sides of the frame. As illustrated, the node 84T_{N} may have a concave cross shape or rectangular (e.g., square) shape with concave corners.

Based on how the thermal pad 84T achieves the above described benefits, it should be appreciated that those benefits are affected by the shapes of the electrical pads 84E and the conductive frame of the thermal pad 84T. For example, in embodiments with round electrical pads 84E, the thermal pad 84T may be formed with a rounded conductive frame to permit an increased metal density of the bonding structure 80 while maintaining a sufficient distance D₂ to decrease parasitic effects. Analogously, in embodiments with rectangular electrical pads 84E, the thermal pad 84T may be formed with a rectangular conductive frame to permit an increased metal density of the bonding structure 80 while maintaining a sufficient distance D₂ to decrease parasitic effects.

In FIG. 3, a semiconductor package 150 is formed by attaching (e.g., bonding) an integrated circuit die 50A (e.g., a first die) to another integrated circuit die 50B (e.g., a second die), in accordance with various embodiments. As discussed above, either or both of the integrated circuit dies 50 may be a logic die (e.g., CPU, GPU, SoC, application processor (AP), microcontroller, etc.), a memory die (e.g., DRAM die, SRAM die, etc.), a power management die (e.g., PMIC die), a radio frequency (RF) die, a sensor die, a MEMS die, a signal processing die (e.g., DSP die), a front-end die (e.g., AFE die), the like, or combinations thereof. Although two integrated circuit dies 50A/50B are described and illustrated, any suitable number of dies may be attached to one another. In some embodiments, the integrated circuit die 50A and the integrated circuit die 50B are same or similar types. In other embodiments, the integrated circuit die 50A is a memory die while the integrated circuit die 50B is a logic die, or vice versa. Either of the integrated circuit dies 50A/50B may be a logic device or a memory device as described above. In some embodiments, the integrated circuit dies 50A/50B may be the same type of dies, such as SoC dies. The integrated circuit dies 50A/50B may be formed in processes of a same technology node, or may be formed in processes of different technology nodes. For example, the integrated circuit die 50B may be of a more advanced process node than the integrated circuit die 50A, or vice versa. Other combinations of the integrated circuit dies 50A/50B may be utilized. Any suitable combinations may be used.

In some embodiments, after forming the bonding structure 80, a singulation process may be performed to separate the integrated circuit die 50 from other integrated circuit dies 50 within the wafer. The singulated integrated circuit dies 50 (e.g., the KGDs among the integrated circuit dies 50) will be attached to other semiconductor components (e.g., another integrated circuit die 50) as discussed below in greater detail. In some embodiments, the integrated circuit die 50 may remain in wafer form and attached to the other semiconductor components in either die or wafer form. For example, integrated circuit dies 50 may be attached together to form the semiconductor package 150, such as a chip-on-wafer (CoW) package on an integrated chip (SoIC) package. In the illustrated embodiments, a bottom die may be a wafer or singulated integrated circuit die 50 and a top die may be a singulated integrated circuit die 50.

The integrated circuit dies 50A/50B may be similar or different embodiments of the integrated circuit die 50 described above in connection with FIGS. 2A through 2C. For example, the integrated circuit dies 50A/50B may be exemplary embodiments described in connection with FIG. 2B, exemplary embodiments described in connection with FIG. 2C, or one of each. As discussed above, the integrated circuit die 50B may remain in wafer form for attachment to the singulated integrated circuit die 50A. Although one integrated circuit die 50A is illustrated, more than one integrated circuit die 50A may be attached to form the semiconductor package 150.

In accordance with various embodiments, the integrated circuit die 50A is bonded to the integrated circuit die 50B through the respective bonding structures 80-each of which including the bonding pads 84 (e.g., electrical pads 84E and thermal pads 84T) and the dielectric bonding layer 82.

Still referring to FIG. 3, the integrated circuit die 50A is bonded to the integrated circuit die 50B, for example, in a dielectric-to-dielectric and metal-to-metal bonding process. The integrated circuit dies 50A/50B are bonded in a face-to-face configuration. For example, the integrated circuit die 50A is illustrated as disposed face down such that the front side of the integrated circuit die 50A faces the front side of the integrated circuit die 50B which is illustrated as disposed face up. The dielectric bonding layer 82 of the integrated circuit die 50A may be directly bonded to the dielectric bonding layer 82 of the integrated circuit die 50B, and the bonding pads 84 of the integrated circuit die 50A may be directly bonded to the bonding pads 84 of the integrated circuit die 50B. For example, the corresponding electrical pads 84E of the integrated circuit dies 50A/50B may be directly bonded, and the corresponding thermal pad 84T of the integrated circuit dies 50A/50B may be directly bonded.

In some embodiments, the bonds between the respective dielectric bonding layers 82 are dielectric-to-dielectric (e.g., oxide-to-oxide) bonds, or the like. The bonding process also directly bonds the respective electrical pads 84E and the respective thermal pads 84T through direct metal-to-metal bonding. Thus, electrical connection between the integrated circuit die 50A and the integrated circuit die 50B is provided by the physical and electrical connection of the electrical pads 84E. In addition, thermal conductivity connection between the integrated circuit die 50A and the integrated circuit die 50B is enhanced by the physical connection of the thermal pads 84T. In some embodiments, the interface also includes dielectric-to-metal interfaces between the integrated circuit dies 50A/50B where the respective electrical pads 84E and/or the thermal pads 84T are not entirely aligned and/or have different dimensions.

The bonding process may start with applying a surface treatment to one or both of the respective bonding structures 80 (e.g., the dielectric bonding layers 82). The surface treatment may include a plasma treatment. The plasma treatment may be performed in a vacuum environment. After the plasma treatment, the surface treatment may further include a cleaning process (e.g., a rinse with deionized water, or the like) that may be applied to one or both of the dielectric bonding layers 82.

After securing the integrated circuit die 50A to a chuck (not specifically illustrated) using a vacuum or a suitable means, the bonding process may proceed by aligning the bonding pads 84 of the integrated circuit die 50A to the bonding pads 84 of the integrated circuit die 50B. When the integrated circuit dies 50A/50B are aligned, corresponding electrical pads 84E and thermal pads 84T may overlap. After alignment, the integrated circuit dies 50A/50B are moved toward one another (e.g., the integrated circuit die 50A is moved downward toward the integrated circuit die 50B).

The bonding includes a pre-bonding step, during which the integrated circuit die 50A is put in contact with the dielectric bonding layer 82 and the bonding pads 84 of the integrated circuit die 50B. In some embodiments (not specifically illustrated), the vacuum or other means of securing the integrated circuit die 50A to the chuck may be adjusted so that a central region of the integrated circuit die 50A bows outward (e.g., downward as illustrated) toward the integrated circuit die 50B. In addition or alternatively, a pin may press against the back side of the integrated circuit die 50A to cause the bowing toward the integrated circuit die 50B. The pre-bonding may be performed at room temperature (e.g., between about 21° C. and about 25° C.). The bonding process continues by performing an anneal, for example, at a temperature between about 150° C. and about 400° C. for a duration between about 0.5 hours and about 3 hours, so that metal of the respective bonding pads 84 (e.g., copper) inter-diffuses with each other, and hence the direct metal-to-metal bonding is formed. Other direct bonding processes (e.g., using adhesives, polymer-to-polymer bonding, or the like) may be used in other embodiments. Notably, the integrated circuit die 50A is bonded to the integrated circuit die 50B without the use of solder connections (e.g., microbumps or the like).

Following the attachment process, the semiconductor package 150 may undergo further processing (not specifically illustrated). For example, a gap-fill material may be formed over and between adjacent integrated circuit dies 50A, additional semiconductor components may be attached to the semiconductor package 150, external connectors may be formed, and/or the semiconductor package 150 may be attached to a package substrate. At any suitable stages, the structure may undergo additional testing (e.g., thermal cycle testing).

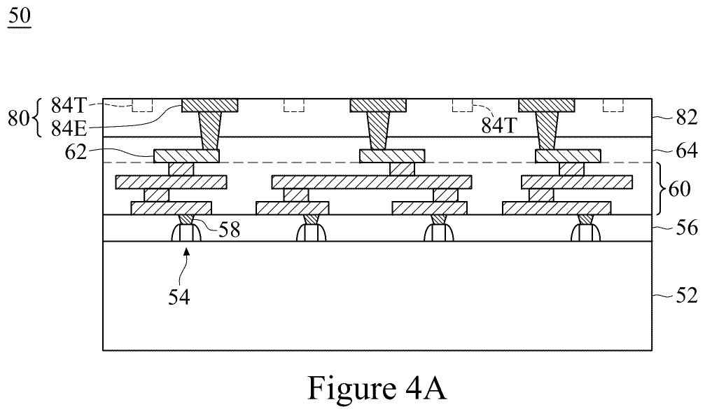

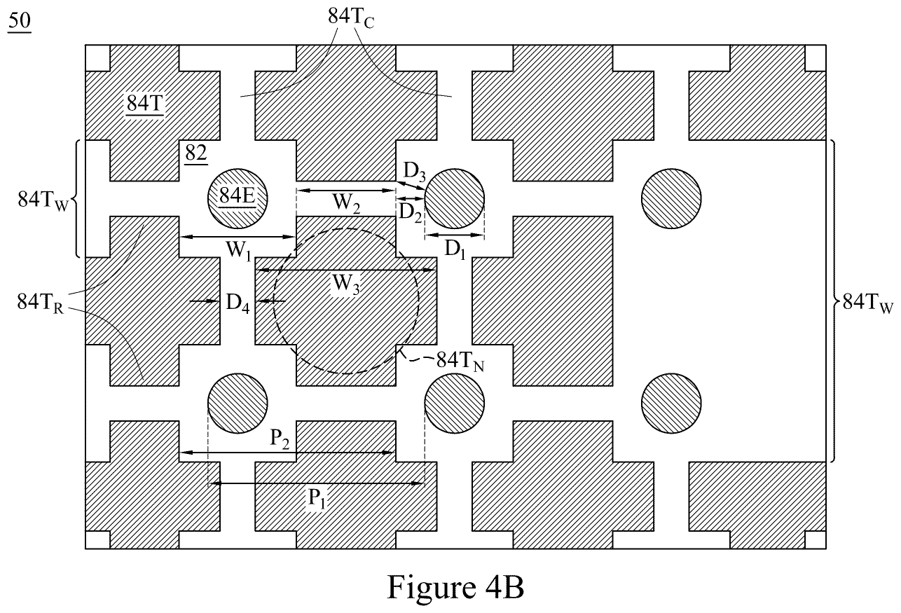

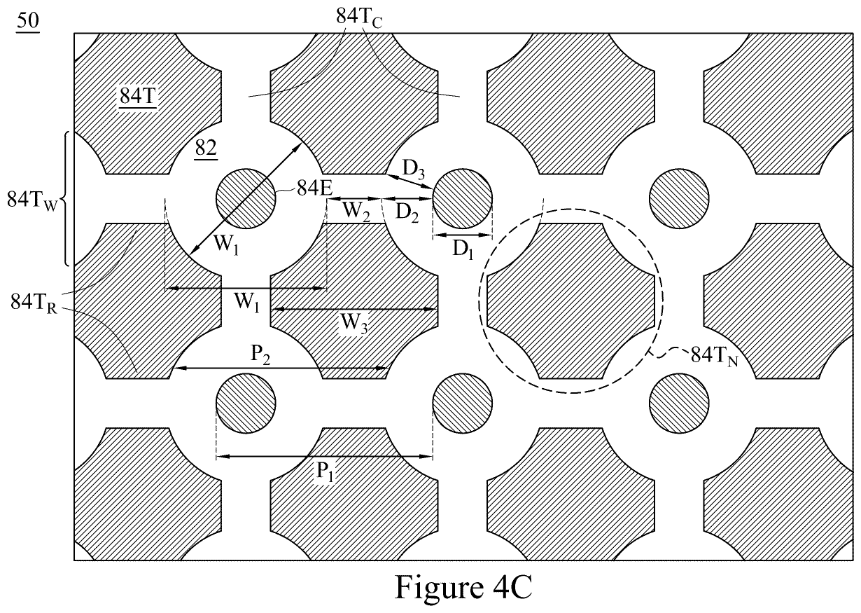

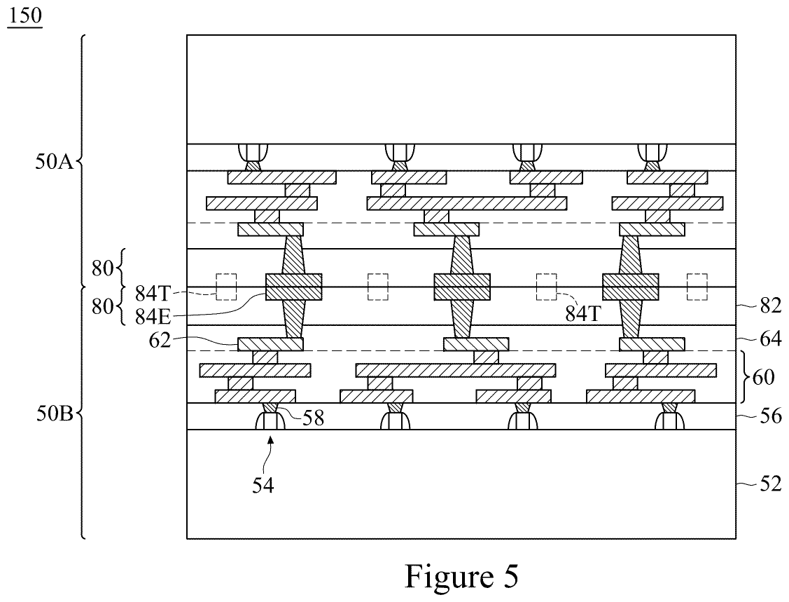

FIGS. 4A through 4C illustrate additional embodiments of the integrated circuit die 50. FIG. 5 illustrates formation of an additional embodiment of the semiconductor package 150. These embodiments may be formed similarly as described above with respect to their analogs, unless otherwise provided.

In FIGS. 4A through 4C, the integrated circuit die 50 may include a thermal pad 84T in the form of a conductive frame, similarly as described above in connection with FIGS. 2B and 2C, respectively, albeit with several differences. For example, the thermal pad 84T may be composed of discontinuous elements (e.g., a discontinuous conductive frame composed of a plurality of discrete thermal pads 84T), such that adjacent windows 84T_{W} are connected to one another by narrow openings or channels 84T_{C}. FIG. 4B illustrates an exemplary discontinuous alternative to the rectangular framework of FIG. 2B, and FIG. 4C illustrates an exemplary discontinuous alternative to the rounded framework of FIG. 2C.

FIGS. 4B and 4C illustrate plan views of the bonding structure 80 (e.g., the dielectric bonding layer 82, the electrical pads 84E, and the thermal pads 84T) of the integrated circuit die 50, in accordance with various embodiments. In the illustrated embodiments, the thermal pad 84T may be a conductive framework (e.g., a conductive frame) extending around and between the electrical pads 84E. FIG. 4B illustrates the thermal pads 84T with rectangular (e.g., square) openings or windows 84T_{W}, and FIG. 4C illustrates the thermal pad 84T with round (e.g., circular) openings or windows 84T_{W}.

An upper surface of the bonding structure 80 has a metal density based on the proportion of the bonding pads 84 embedded in the dielectric bonding layer 82. For example, due to presence of the thermal pads 84T, the metal density may range from 50% to 60%. In such embodiments, the electrical pads 84E may account for about 10% or less of the metal density and the thermal pads 84T account for a remainder of the metal density. For example, presence of the thermal pads 84T may increase the metal density by 5 to 6 times. As a result, thermal resistance of the integrated circuit die 50 may be reduced by up to 85% to 90%, thereby improving thermal dissipation benefits of the integrated circuit die 50. A metal density greater than 50% ensures sufficient thermal dissipation benefits. In addition, a metal density of lesser than 60% ensures that the upper surface of the bonding structure 80 includes a sufficient proportion of the dielectric bonding layer 82 for reliable bonding (see FIG. 5).

Referring to FIG. 4B, the conductive frame of the thermal pad 84T may comprise rectangular (e.g., square) windows 84T_{W} substantially bounded by perpendicular rails 84T_{R} and connected by the channels 84C. As illustrated, the windows 84T_{W} contain the electrical pads 84E within. Optionally, some of the windows 84T_{W} may be large enough to contain two, four, or more of the electrical pads 84E, such as the window 84T_{W} illustrated in the right-hand portion of FIG. 4B.

As further illustrated, the electrical pads 84E may be viewed as framing at least a portion of the thermal pads 84T. For example, similarly as described above in connection with FIG. 2B, a portion of the thermal pad 84T where four rails 84T_{R} meet or intersect (e.g., a node 84T_{N}) is framed by at least four electrical pads 84E, such that four of these electrical pads 84E comprise four corners of a frame around the thermal pad 84T. In some embodiments, others of these electrical pads 84E may comprise portions of one or more sides of the frame. As noted above, an entirety of this contiguous portion of the thermal pad 84T may be referred to as the node 84T_{N}. In particular, these four electrical pads 84E comprise four corners of a frame around this portion of the thermal pad 84T. As illustrated, the node 84T_{N} may have a cross or rectangular (e.g., square) shape.

To achieve analogous benefits, the relative dimensions of the features may be similar as described above in connection with FIG. 2B, except as otherwise stated. These dimensions include the pitch PI of the electrical pads 84E, the diameter D₁ (e.g., the critical dimension) of the electrical pads 84E, the width W, of the windows 84T_{W}, the width W₂ of the rails 84T_{R}, the distance D₂ of the rails 84T_{R} (e.g., an imaginary line along the rails 84T_{R} where the channels 84C are located), and the pitch P₂ of the thermal pads 84T. In addition, a width W₃ of the thermal pads 84T indicates a spacing between adjacent and parallel channels 84T_{C}. As illustrated, a most proximal point of the thermal pad 84T may be a distance D₃ from the electrical pads 84E. In some embodiments, the bonding structure 80 may be formed to achieve a similar metal density as that discussed above in connection with FIG. 2B, while maintaining a sufficient distance D₃ (e.g., in comparison with the distance D₂ of FIG. 2B) to prevent parasitic effects.

Referring to FIG. 4C, the conductive frame of the thermal pads 84T may comprise round (e.g., circular or oval) windows 84T_{W} substantially bounded by convex rails 84T_{R} and connected by the channels 84C. As illustrated, the windows contain the electrical pads 84E within. In some embodiments (not specifically illustrated), some of the windows 84T_{W} may contain two, four, or more of the electrical pads 84E. To achieve analogous benefits, the relative dimensions of the features may be similar as described above in connection with FIG. 2B, except as otherwise stated. These dimensions include the pitch PI of the electrical pads 84E, the diameter D₁ of the electrical pads 84E, the width W, of the window 84T_{W}, the width W₂ of the rails 84T_{R}, the distance D₂ of the rails 84T_{R} (e.g., an imaginary line along the rails 84T_{R} where the channels 84C are located), and the pitch P₂ of the thermal pads 84T. In addition, a width W₃ of the thermal pads 84T indicates a spacing between adjacent and parallel channels 84T_{C}. As illustrated, a most proximal point of the thermal pads 84T may be a distance D₃ from the electrical pads 84E which may be about constant around perimeters of the electrical pads 84E. In some embodiments, the bonding structure 80 may be formed to achieve a similar metal density as that discussed above in connection with FIG. 2C, while maintaining a sufficient distance D₃ (e.g., in comparison with the distance D₂ of FIG. 2C) to prevent parasitic effects.

As further illustrated, the electrical pads 84E may be viewed as framing at least a portion of the thermal pads 84T. For example, similarly as described above in connection with FIG. 2C, a portion of the thermal pad 84T where four rails 84T_{R} meet or intersect (e.g., a node 84T_{N}) is framed by at least four electrical pads 84E, such that four of these electrical pads 84E comprise four corners of a frame around the thermal pad 84T. In some embodiments, others of these electrical pads 84E may comprise portions of one or more sides of the frame. As noted above, an entirety of this contiguous portion of the thermal pad 84T may be referred to as the node 84T_{N}. In particular, these four electrical pads 84E comprise four corners of a round (e.g., circular or oval) frame around this portion of the thermal pad 84T. As illustrated, the node 84T_{N} may have a concave cross shape or rectangular (e.g., square) shape with concave corners.

Although the embodiments of FIGS. 4B and 4C utilize more complicated patterns than the embodiments of FIGS. 2B and 2C, the present embodiments may achieve additional benefits. In particular, the discontinuous conductive frame of the thermal pads 84T further reduces risk of parasitic effects by being divided into discrete components. In addition, the additional openings (e.g., the channels 84T_{C}) between the thermal pads 84T may reduce risk of misalignment during a subsequent bonding process and/or may reduce costs of fabrication by using less conductive material. Further, in regard to the embodiments of FIG. 4B, the channels 84C are at the locations along the windows 84T_{W} that would otherwise be most proximal to the bonding pads 84. As a result, the most proximal points are at a distance D₃ from the bonding pads 84, which may be greater than the distance D₂. Alternatively or in addition, the width W₁ of the windows 84T_{W} may be smaller so that the distance D₂ may be less than the distance D₂ discussed above in connection with FIG. 2B.

In FIG. 5, a semiconductor package 150 is formed by attaching (e.g., bonding) an integrated circuit die 50A (e.g., a first die) to another integrated circuit die 50B (e.g., a second die), in accordance with various embodiments. The attachment process may be performed similarly as described above in connection with FIG. 3. The integrated circuit dies 50A/50B may be similar or different embodiments of the integrated circuit die 50 described above in connection with FIGS. 4A through 4C. For example, the integrated circuit dies 50A/50B may be exemplary embodiments described in connection with FIG. 4B, exemplary embodiments described in connection with FIG. 4C, or one of each. In addition, either of the integrated circuit dies 50A/50B may be an exemplary embodiment discussed above in connection with FIGS. 2A through 2C. As such, the patterns of the corresponding bonding structures 80 of the integrated circuit dies 50A/50B may differ such that some portions of the thermal pads 84T may align with corresponding portions of the dielectric bonding layer 82 (e.g., locations of the channels 84T_{C}) of the opposing integrated circuit die 50A/50B.

As discussed above, following the attachment process, the semiconductor package 150 may undergo further processing (not specifically illustrated). For example, a gap-fill material may be formed over and between adjacent integrated circuit dies 50A, additional semiconductor components may be attached to the semiconductor package 150, external connectors may be formed, and/or the semiconductor package 150 may be attached to a package substrate. At any suitable stages, the structure may undergo additional testing (e.g., thermal cycle testing).

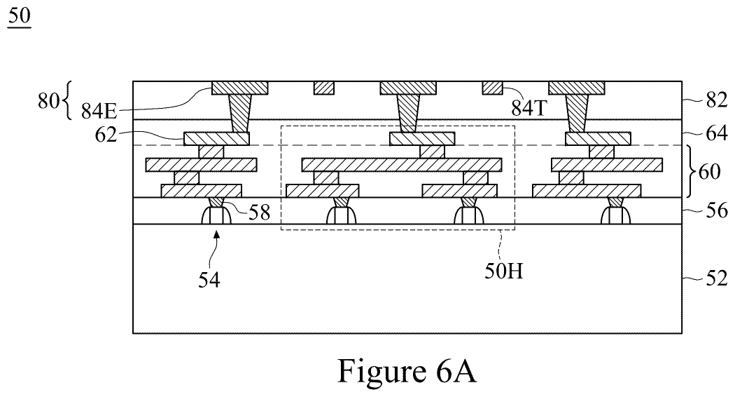

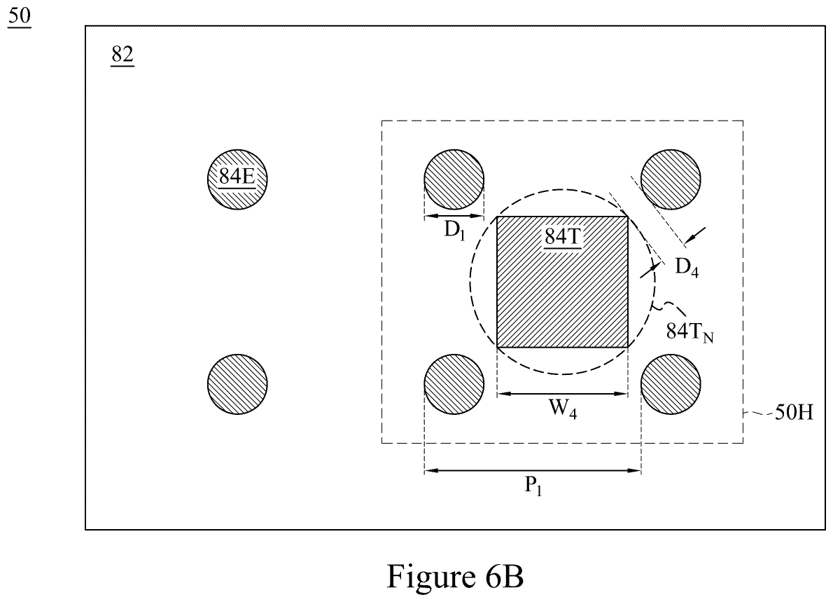

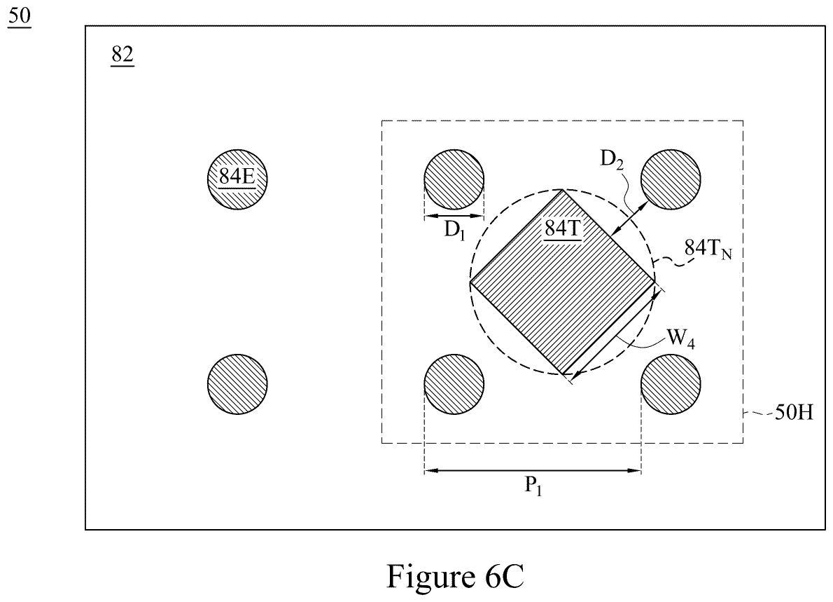

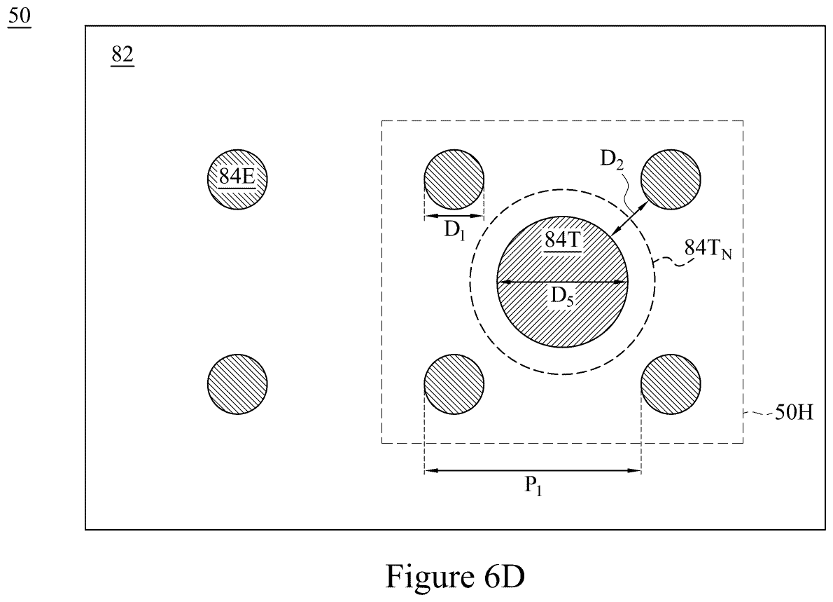

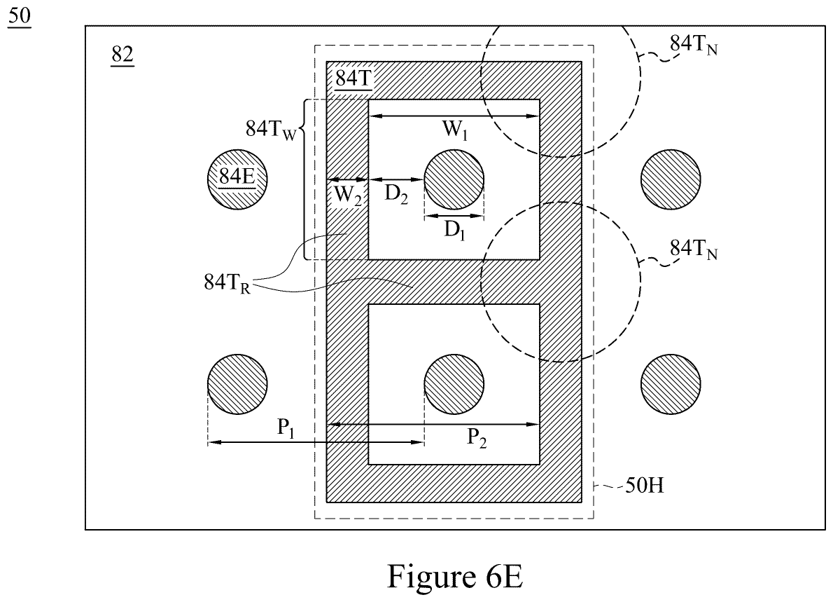

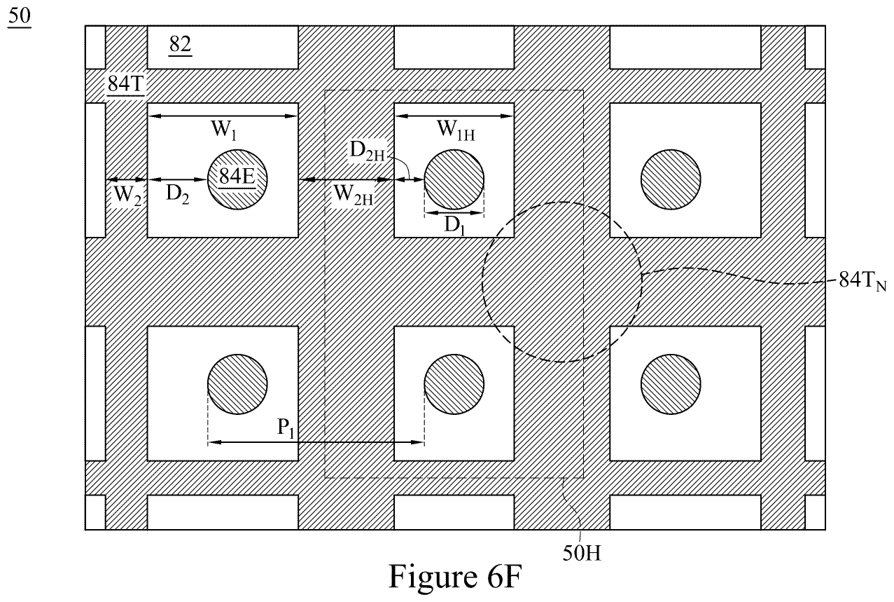

In FIGS. 6A through 6E, the integrated circuit die 50 may include a thermal pad 84T with a particular shape or location to provide greater thermal dissipation from particular locations of the integrated circuit die 50 as compared to other locations of the integrated circuit die 50. For example, the integrated circuit of the integrated circuit die 50 may include hot zones 50H which generate or accumulate heat at higher rates than other regions of the integrated circuit die 50. In some embodiments, the hot zones 50H may be located where the integrated circuit die 50 contains higher power density, such as in a core region. In accordance with various embodiments, the thermal pads 84T may include discrete conductive elements located between some of the electrical pads 84E (see FIGS. 6B through 6D), discrete conductive frames located between and around some or all of the bonding pads 84 (see FIGS. 6E and 6F), or combinations thereof.

In accordance with various embodiments, the thermal pad 84T may reduce a local thermal resistance within the hot zone 50H by as much as 85% to 90%. This benefit may be achieved with a local metal density (e.g., the thermal pad(s) 84T and the electrical pads 84E within the hot zone 50H) ranging from 50% to 60%, wherein the electrical pads 84E account for about 10% or less and the thermal pad 84T accounts for a remainder of the metal density. For example, presence of the thermal pad 84T may increase the metal density by 5 times to 6 times.

FIG. 6B illustrates a plan view of the thermal pad 84T being interposed between several of the electrical pads 84E, wherein the thermal pad 84T has a rectangular (e.g., square) shape. This shape is advantageous for thermal dissipation of the hot zone 50H due to corners of the rectangle being proximal to the electrical pads 84E. This shape is additionally advantageous for direct bonding due to achieving the thermal dissipation benefits with a lower local metal density.

As illustrated, the electrical pads 84E may have a diameter D₁ and a pitch P₁ as described above in connection with previous embodiments. In addition, the illustrated element of the thermal pad 84T may have a width W₄ ranging from 2 times the diameter D₁ to 0.8 times the pitch P₁. As a result, the illustrated element maintains a distance D₄ from the electrical pads 84E that is great enough to prevent parasitic effects.

As further illustrated, the electrical pads 84E may be viewed as framing at least a portion of the thermal pad 84T. For example, similarly as described above, a portion of the thermal pad 84T may be framed by at least four electrical pads 84E, such that four of these electrical pads 84E comprise four corners of a frame around the thermal pad 84T. In some embodiments, others of these electrical pads 84E may comprise portions of one or more sides of the frame. As noted above, an entirety of this contiguous portion of the thermal pad 84T may be referred to as the node 84T_{N}. In particular, these four electrical pads 84E comprise four corners of a frame around this portion of the thermal pad 84T. As illustrated, an entirety of the thermal pad 84T may be framed, and the node 84T_{N} accordingly has the same rectangular (e.g., square) shape.

FIG. 6C illustrates a plan view of the thermal pad 84T being interposed between several of the electrical pads 84E, wherein the thermal pad 84T has a parallelogram (e.g., rhomboid or diamond) shape. This shape is advantageous for thermal dissipation of the hot zone 50H by increasing the local metal density while remaining far enough from the electrical pads 84E to prevent parasitic effects.

As illustrated, the electrical pads 84E may have a diameter D₁ and a pitch P₁ as described above in connection with previous embodiments. In addition, the illustrated embodiment of the thermal pad 84T may have a width W₄ ranging from 2 or 3 times the diameter D₁ to substantially equal to the pitch P₁ (e.g., up to 1.1 times the pitch P₁). As a result, the illustrated element maintains a distance D₂ from the bonding pads 84 that is great enough to prevent parasitic effects.

As further illustrated, the electrical pads 84E may be viewed as framing at least a portion of the thermal pad 84T. For example, similarly as described above, a portion of the thermal pad 84T may be framed by at least four electrical pads 84E, such that four of these electrical pads 84E comprise four corners of a frame around the thermal pad 84T. In some embodiments, others of these electrical pads 84E may comprise portions of one or more sides of the frame. As noted above, an entirety of this contiguous portion of the thermal pad 84T may be referred to as the node 84T_{N}. In particular, these four electrical pads 84E comprise four corners of a frame around this portion of the thermal pad 84T. As illustrated, an entirety of the thermal pad 84T may be framed, and the node 84T_{N} accordingly has the same parallelogram (e.g., rhomboid or diamond) shape.

FIG. 6D illustrates a plan view of the thermal pad 84T being interposed between several of the electrical pads 84E, wherein the thermal pad 84T has a rounded or an oval (e.g., circular) shape. This shape is advantageous for thermal dissipation of the hot zone 50H while simplifying the process steps (e.g., the patterning and conductive material deposition processes) by reducing numbers of sharp edges and sharp corners from the bonding structure 80.

As illustrated, the electrical pads 84E may have a diameter D₁ and a pitch PI as described above in connection with previous embodiments. In addition, the illustrated element of the thermal pad 84T may have a diameter Ds ranging from 2 or 3 times the diameter D₁ to substantially equal to the pitch P₁ (e.g., up to 1.1 times the pitch P₁). As a result, the illustrated element maintains a distance D₂ from the bonding pads 84 that is great enough to prevent parasitic effects.

As further illustrated, the electrical pads 84E may be viewed as framing at least a portion of the thermal pad 84T. For example, similarly as described above, a portion of the thermal pad 84T may be framed by at least four electrical pads 84E, such that four of these electrical pads 84E comprise four corners of a frame around the thermal pad 84T. In some embodiments, others of these electrical pads 84E may comprise portions of one or more sides of the frame. As noted above, an entirety of this contiguous portion of the thermal pad 84T may be referred to as the node 84T_{N}. In particular, these four electrical pads 84E comprise four corners of a frame around this portion of the thermal pad 84T. As illustrated, an entirety of the thermal pad 84T may be framed, and the node 84T_{N} accordingly has the same oval (e.g., circular) shape.

FIG. 6E illustrates a plan view of the thermal pad 84T being a partial conductive frame extending around and between some of the electrical pads 84E, in accordance with various embodiments. This partial frame is advantageous for thermal dissipation of the hot zone 50H similarly as described above in connection with FIGS. 2B, 2C, 4B, and 4C. However, the partial frame provides an advantage of focusing the thermal dissipation benefits in particular locations, while maintaining a lower total metal density across the bonding structure 80 to improve the direct bonding process. In accordance with various embodiments, the thermal pad 84T may be a rounded conductive frame as described above in connection with FIG. 2C and/or a discontinuous conductive frame as described above in connection with FIGS. 4B and 4C. As such, the bonding structure 80 (including the thermal pad 84T) may include the dimensions described above in connection with FIGS. 2A through 2C and 4A through 4C.

As further illustrated, the electrical pads 84E may be viewed as framing at least a portion of the thermal pad 84T. For example, a portion of the thermal pad 84T where four rails 84T_{R} meet or intersect (e.g., a node 84T_{N}) is framed by at least four electrical pads 84E. In particular, four of these electrical pads 84E comprise four corners of a frame around this portion of the thermal pad 84T. As illustrated, the node 84T_{N} may have a T-shape (e.g., a T-junction shape), an L-shape, or the like based on the layouts of the electrical pads 84E and the frame of the thermal pad 84T.

FIG. 6F illustrates a plan view of a variation of the thermal pads 84T described above in connection with FIGS. 2A through 2C and 4A through 4C, wherein the windows 84T_{W} and the rails 84T_{R} may include varying dimensions. In particular, the thermal pad 84T may be a conductive frame (or discontinuous conductive frame) with greater density over the hot zones 50H as compared to other regions of the integrated circuit die 50. As such, the total metal density may be decreased to improve the direct bonding process. Although illustrated as a continuous rectangular frame (e.g., analogous to FIG. 2B), the thermal pad 84T may be an analogous variation of the other exemplary shapes and styles of the conductive frame (see FIGS. 2C, 4B, and 4C).

For example, the bonding structure 80 (including the thermal pad 84T) may include the dimensions within the ranges described above in connection with FIGS. 2A through 2C and 4A through 4C. In particular, a width W_{1H} of the window 84T_{W} over the hot zone 50H and a distance D_{2H} of the thermal pad 84T from the electrical pads 84E may be near the lower points of the associated ranges for the width W, and the distance D₂, respectively. In addition, a width W_{2H} of the rail 84T_{R} may be near the upper points of the associated range for the width W₂. Further, the reverse may be true for those dimensions in regions of the thermal pad 84T that are distal from the hot zone 50H.

As further illustrated, the electrical pads 84E may be viewed as framing at least a portion of the thermal pad 84T. For example, a portion of the thermal pad 84T where four rails 84T_{R} meet or intersect (e.g., a node 84T_{N}) is framed by at least four electrical pads 84E. In particular, four of these electrical pads 84E comprise four corners of a frame around this portion of the thermal pad 84T. In some embodiments, others of these electrical pads 84E may comprise portions of one or more sides of the frame. As illustrated, the node 84T_{N} may have a cross or rectangular shape, or a T-shape, an L-shape, or the like in cases of this frame also being analogous to FIG. 6E and accompanying discussion.

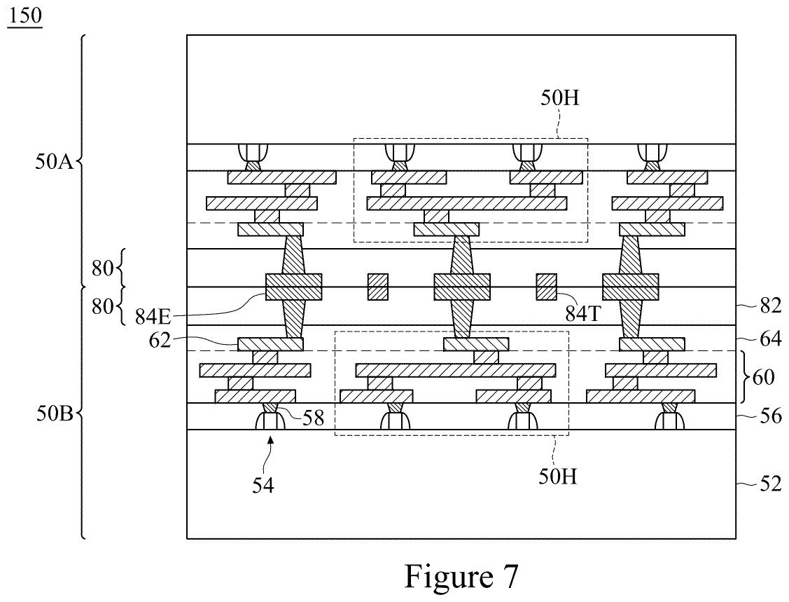

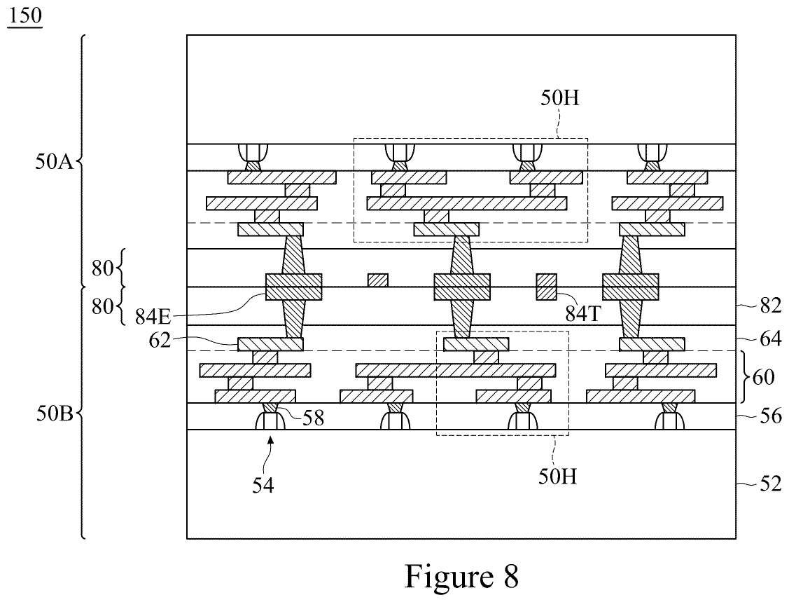

FIGS. 7 and 8 illustrate attachment of an integrated circuit die 50A to an integrated circuit die 50B to form a semiconductor package 150, in accordance with various embodiments. The attachment process may be performed as described above in connection with FIGS. 3 and 5. The integrated circuit dies 50A/50B may be similar or different embodiments of the integrated circuit die 50 described above in connection with FIGS. 6A through 6F (including combinations thereof) and/or described above in connection with other embodiments.

In some embodiments, the thermal pads 84T of the integrated circuit die 50A are disposed over the hot zone 50H of the integrated circuit die 50A, and the thermal pads 84T of the integrated circuit die 50B are disposed over the hot zone 50H of the integrated circuit die 50B. FIG. 7 provides an exemplary embodiment in which hot zones 50H of the integrated circuit dies 50A/50B align such that the corresponding thermal pads 84T are paired and may also substantially align. FIG. 8 provides an exemplary embodiment in which hot zones 50H of the integrated circuit die 50A/50B overlap without necessarily aligning such that some of the corresponding thermal pads 84T are paired while other thermal pads 84T may remain unpaired.

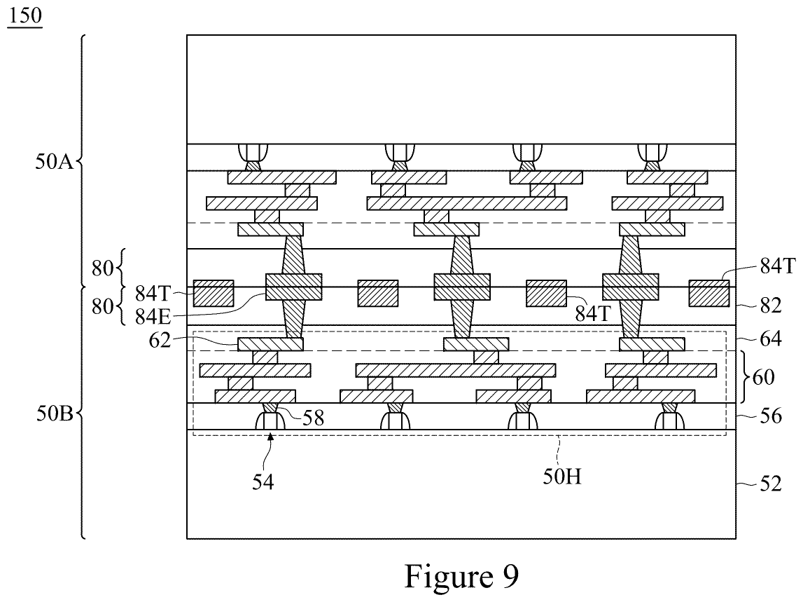

FIGS. 9 and 10 illustrate additional embodiments of the integrated circuit dies 50A/50B attached to form a semiconductor package 150, in accordance with various embodiments. In particular, these embodiments may include examples or variations of any applicable embodiments of the integrated circuit dies 50 to form variations of the semiconductor packages 150 described above.

In FIG. 9, the thermal pads 84T may be formed to thicknesses that differ from a thickness of the landing pad portions of the electrical pads 84E. For example, as illustrated with respect to the integrated circuit die 50A, the thermal pads 84T may have a lesser thickness than the landing pad portions of the electrical pads 84E. In addition, as illustrated with respect to the integrated circuit die 50B, the thermal pads 84T may have a greater thickness than the landing pad portions of the electrical pads 84E. It should be appreciated that any combinations of these thermal pads 84T (e.g., having greater, lesser, or equal thickness) may be included in any of the integrated circuit dies 50A/50B.

In accordance with some embodiments, the thermal pads 84T may be formed partially in parallel with the electrical pads 84E. For example, openings for the thermal pads 84T may be formed separately from openings for the electrical pads 84E in order to etch differing shapes and depths. After forming both sets of openings, conductive material may be deposited and planarized for the electrical pads 84E and the thermal pads 84T simultaneously, similarly as described above.

Embodiments relating to the thermal pads 84T having greater thicknesses than the electrical pads 84E may provide greater thermal dissipation benefits in the integrated circuit dies 50 (or particular locations therein, e.g., hot zones 50H). Conversely, embodiments relating to the thermal pads 84T having a lesser thickness than the electrical pads 84E may achieve sufficient thermal dissipation benefits in the integrated circuit dies 50 (or particular locations therein, as desired) while utilizing less conductive material.

In FIG. 10, the thermal pads 84T may be formed to include both landing pad portions and via portions, similarly as described in connection with the electrical pads 84E (see, e.g., FIGS. 2A through 2C). As such, the thermal pads 84T and the electrical pads 84E may be formed simultaneously in either a dual damascene process or multiple single damascene processes. For example, as illustrated with respect to the integrated circuit die 50A, all of the thermal pads 84T may be formed to include both landing pad portions and via portions. In addition, as illustrated with respect to the integrated circuit die 50B, some of the thermal pads 84T located over hot zones 50H may be formed to include both landing pad portions and via portions, while others of the thermal pads 84T (e.g., laterally displaced from the hot zones 50H) may be formed with landing pad portions and without via portions. Each type of the thermal pads 84T may be formed similarly as described above in analogous embodiments.

In some embodiments, the via portions of the thermal pads 84T may extend to substantially the same depth as the via portions of the electrical pads 84E. In other embodiments (not specifically illustrated), the via portions of the thermal pads 84T may extend to greater or lesser depths than the via portions of the electrical pads 84E. Moreover, the depths of the via portions of the thermal pads 84T may be varied within the integrated circuit die 50. For example, the depths of the via portions of some of the thermal pads 84T may be greater in order to increase thermal dissipation benefits in those locations, and the depths of the via portions of others of the thermal pads 84T may be lesser in order to reduce parasitic effects with proximal conductive features (e.g., the pads 62). Moreover, some of the thermal pads 84T may extend to some of the pads 62, such as dummy metal pads 62 that may be electrically isolated from the integrated circuit.

As discussed above, following the attachment process, the semiconductor package 150 may undergo further processing (not specifically illustrated). For example, a gap-fill material may be formed over and between adjacent integrated circuit dies 50A, additional semiconductor components may be attached to the semiconductor package 150, external connectors may be formed, and/or the semiconductor package 150 may be attached to a package substrate. At any suitable stages, the structure may undergo additional testing (e.g., thermal cycle testing).

Various advantages are achieved. In particular, the bonding structure 80 may be formed with the thermal pads 84T to improve thermal dissipation from the integrated circuit of the integrated circuit die 50. For example, embodiments of the thermal pad 84T may include a continuous or discontinuous conductive frame extending around and between the electrical pads 84E. In addition, embodiments of the thermal pad 84T may include elements located proximately to the hot zones 50H of the integrated circuit die 50. Further, embodiments of the thermal pad 84T may include a partial conductive frames located proximately to hot zones 50H or a conductive frame with greater local metal density located proximately to the hot zones 50H. As a result, the thermal pads 84T may be formed in parallel with the electrical pads 84E so that zero or few additional process steps are needed to fabricate the semiconductor package 150 and achieve the thermal dissipation benefits.

In an embodiment, a method includes forming a device layer along a substrate; forming a first interconnect structure over the device layer; forming a metal pad over the first interconnect structure; forming first bonding pads over and electrically connected to the first interconnect structure; and forming a second bonding pad over and electrically isolated from the first interconnect structure, in a plan view the first bonding pads comprising four corners of a frame around a portion of the second bonding pad. In another embodiment, the method further includes bonding an integrated circuit die to the first bonding pads and the second bonding pad. In another embodiment, the integrated circuit die comprises: a second interconnect structure; third bonding pads, the third bonding pads electrically connecting the second interconnect structure to the first bonding pad; and a fourth bonding pad in physical contact with the second bonding pad. In another embodiment, the fourth bonding pad is electrically isolated from the second interconnect structure. In another embodiment, the first bonding pads and the second bonding pad are embedded in a first dielectric bonding layer, wherein the third bonding pads and the fourth bonding pad are embedded in a second dielectric bonding layer, and wherein bonding the integrated circuit die comprises: directly bonding the first dielectric bonding layer to the second dielectric bonding layer; directly bonding the first bonding pads to the third bonding pads; and directly bonding the second bonding pad to the fourth bonding pad. In another embodiment, in the plan view the second bonding pad forms a rectangular ring around one pad of the first bonding pads. In another embodiment, in the plan view the second bonding pad forms a round ring around one pad of the first bonding pads. In another embodiment, the second bonding pad forms a continuous conductive frame around and between each of the first bonding pads. In another embodiment, forming the second bonding pad comprises forming a plurality of bonding pads, and wherein the plurality of bonding pads form a discontinuous conductive frame around and between each of the first bonding pads.

In an embodiment, a semiconductor device includes an active device along a substrate; an interconnect structure over the active device, the interconnect structure comprising a metal pad; a dielectric bonding layer over the metal pad; a first bonding pad embedded the dielectric bonding layer, the first bonding pad being electrically connected to the metal pad; and a second bonding pad embedded in the dielectric bonding layer, the second bonding pad being electrically isolated from the interconnect structure, in a plan view the second bonding pad comprising a conductive frame around the first bonding pad. In another embodiment, the conductive frame is continuous. In another embodiment, the conductive frame is discontinuous. In another embodiment, in the plan view the first bonding pad has a circular shape, and wherein in the plan view the conductive frame has a square shape. In another embodiment, in the plan view the first bonding pad has a circular shape, and wherein in the plan view the conductive frame of the second bonding pad has a circular ring shape. In another embodiment, the first bonding pad comprises a plurality of bonding pads, and wherein the conductive frame of the second bonding pad extends around and between each one of the plurality of bonding pads.

In an embodiment, a semiconductor device includes a first integrated circuit over a first substrate, the first integrated circuit comprising: a first device layer; a first interconnect structure; and a first metal pad; a first bonding structure over the first integrated circuit, the first bonding structure comprising: a first dielectric bonding layer; a first electrical bonding pad embedded in the first dielectric bonding layer, the first electrical bonding pad being electrically connected to the first metal pad and the first interconnect structure; and a first thermal bonding pad embedded in the first dielectric bonding layer, the first thermal bonding pad being electrically isolated from the first interconnect structure; a second bonding structure over and physically contacting the first bonding structure; and a second integrated circuit over the second bonding structure. In another embodiment, wherein the second bonding structure comprises: a second dielectric bonding layer being bonded to the first dielectric bonding layer; a second electrical bonding pad embedded in the second dielectric bonding layer; and a second thermal bonding pad embedded in the second dielectric bonding layer. In another embodiment, the second electrical bonding pad is bonded to the first electrical bonding pad, and wherein the second thermal bonding pad is bonded to the first thermal bonding pad. In another embodiment, the second electrical bonding pad is electrically connected to the second integrated circuit, and wherein the second thermal bonding pad is electrically isolated from the first integrated circuit and the second integrated circuit. In another embodiment, in a plan view the first thermal bonding pad comprises a continuous conductive frame around the first electrical bonding pad, and wherein in the plan view the second thermal bonding pad comprises a discontinuous conductive frame around the second electrical bonding pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a device layer along a substrate;
forming a first interconnect structure over the device layer;
forming a metal pad over the first interconnect structure;
forming first bonding pads over and electrically connected to the first interconnect structure; and
forming a second bonding pad over and electrically isolated from the first interconnect structure, in a plan view the first bonding pads comprising four corners of a frame around a portion of the second bonding pad.

2. The method of claim 1, further comprising bonding an integrated circuit die to the first bonding pads and the second bonding pad.

3. The method of claim 2, wherein the integrated circuit die comprises:
a second interconnect structure;
third bonding pads, the third bonding pads electrically connecting the second interconnect structure to the first bonding pad; and
a fourth bonding pad in physical contact with the second bonding pad.

4. The method of claim 3, wherein the fourth bonding pad is electrically isolated from the second interconnect structure.

5. The method of claim 3, wherein the first bonding pads and the second bonding pad are embedded in a first dielectric bonding layer, wherein the third bonding pads and the fourth bonding pad are embedded in a second dielectric bonding layer, and wherein bonding the integrated circuit die comprises:
directly bonding the first dielectric bonding layer to the second dielectric bonding layer;
directly bonding the first bonding pads to the third bonding pads; and
directly bonding the second bonding pad to the fourth bonding pad.

6. The method of claim 1, wherein in the plan view the second bonding pad forms a rectangular ring around one pad of the first bonding pads.

7. The method of claim 1, wherein in the plan view the second bonding pad forms a round ring around one pad of the first bonding pads.

8. The method of claim 1, wherein the second bonding pad forms a continuous conductive frame around and between each of the first bonding pads.

9. The method of claim 1, wherein forming the second bonding pad comprises forming a plurality of bonding pads, and wherein the plurality of bonding pads form a discontinuous conductive frame around and between each of the first bonding pads.

10. A semiconductor device comprising:
an active device along a substrate;
an interconnect structure over the active device, the interconnect structure comprising a metal pad;
a dielectric bonding layer over the metal pad;
a first bonding pad embedded the dielectric bonding layer, the first bonding pad being electrically connected to the metal pad; and
a second bonding pad embedded in the dielectric bonding layer, the second bonding pad being electrically isolated from the interconnect structure, in a plan view the second bonding pad comprising a conductive frame around the first bonding pad.

11. The semiconductor device of claim 10, wherein the conductive frame is continuous.

12. The semiconductor device of claim 10, wherein the conductive frame is discontinuous.

13. The semiconductor device of claim 10, wherein in the plan view the first bonding pad has a circular shape, and wherein in the plan view the conductive frame has a square shape.

14. The semiconductor device of claim 10, wherein in the plan view the first bonding pad has a circular shape, and wherein in the plan view the conductive frame of the second bonding pad has a circular ring shape.

15. The semiconductor device of claim 10, wherein the first bonding pad comprises a plurality of bonding pads, and wherein the conductive frame of the second bonding pad extends around and between each one of the plurality of bonding pads.

16. A semiconductor device comprising:
a first integrated circuit over a first substrate, the first integrated circuit comprising:
a first device layer;
a first interconnect structure; and
a first metal pad;
a first bonding structure over the first integrated circuit, the first bonding structure comprising:
a first dielectric bonding layer;
a first electrical bonding pad embedded in the first dielectric bonding layer, the first electrical bonding pad being electrically connected to the first metal pad and the first interconnect structure; and
a first thermal bonding pad embedded in the first dielectric bonding layer, the first thermal bonding pad being electrically isolated from the first interconnect structure;
a second bonding structure over and physically contacting the first bonding structure; and
a second integrated circuit over the second bonding structure.

17. The semiconductor device of claim 16, wherein the second bonding structure comprises:
a second dielectric bonding layer being bonded to the first dielectric bonding layer;
a second electrical bonding pad embedded in the second dielectric bonding layer; and
a second thermal bonding pad embedded in the second dielectric bonding layer.

18. The semiconductor device of claim 17, wherein the second electrical bonding pad is bonded to the first electrical bonding pad, and wherein the second thermal bonding pad is bonded to the first thermal bonding pad.

19. The semiconductor device of claim 18, wherein the second electrical bonding pad is electrically connected to the second integrated circuit, and wherein the second thermal bonding pad is electrically isolated from the first integrated circuit and the second integrated circuit.

20. The semiconductor device of claim 17, wherein in a plan view the first thermal bonding pad comprises a continuous conductive frame around the first electrical bonding pad, and wherein in the plan view the second thermal bonding pad comprises a discontinuous conductive frame around the second electrical bonding pad.
